(19) United States
(12) Patent Application Publication
(10) Pub. No.: US 2026/0173504 A1
(43) Pub. Date: Jun. 18, 2026

(54) NITRIDE SEMICONDUCTOR DEVICE

(71) Applicant: Panasonic Holdings Corporation, Osaka (JP)

(72) Inventor: Satoshi TAMURA, Osaka (JP)

(21) Appl. No.: 19/535,469

(22) Filed: Feb. 10, 2026

Related U.S. Application Data
(63) Continuation of application No. PCT/JP2024/015675, filed on Apr. 22, 2024.

(30) Foreign Application Priority Data
Aug. 28, 2023 (JP) 2023-138130

(51) Int. Cl. H10D 84/80; H10D 30/47; H10D 62/10; H10D 62/824; H10D 64/27

(52) U.S. Cl. CPC H10D 84/811; H10D 30/475; H10D 30/476; H10D 30/477; H10D 62/103; H10D 62/124; H10D 62/824; H10D 64/411

(57) ABSTRACT

A nitride semiconductor device including: a substrate; a channel layer provided above the substrate; a vertical transistor provided in a first region, the vertical transistor being a normally-on transistor; and a lateral transistor provided in a second region, the lateral transistor being a normally-off transistor, in which the vertical transistor includes: a first portion that is a portion of the channel layer and overlaps the first region in a plan view of the substrate; a first gate electrode; and a first drain electrode, the lateral transistor includes: a second portion that is a portion of the channel layer and overlaps the second region in the plan view; a second gate electrode; and a second source electrode, the first gate electrode and the second source electrode are electrically connected to each other, and a source potential of the vertical transistor and a drain potential of the lateral transistor are equal.

### CROSS REFERENCE TO RELATED APPLICATIONS

This is a continuation application of PCT International Application No. PCT/JP2024/015675 filed on Apr. 22, 2024, designating the United States of America, which is based on and claims priority of Japanese Patent Application No. 2023-138130 filed on Aug. 28, 2023. The entire disclosures of the above-identified applications, including the specifications, drawings and claims are incorporated herein by reference in their entirety.

### FIELD

The present disclosure relates to a nitride semiconductor device.

### BACKGROUND

Nitride semiconductors represented by gallium nitride (GaN) are wide-bandgap semiconductors and have the advantages of a high dielectric breakdown field and a high electron saturation drift velocity as compared to existing silicon (Si) semiconductors and gallium arsenide (GaAs), for example. Therefore, research and development is being actively conducted for power transistors that include nitride semiconductors and are suited for higher breakdown voltage, higher power, and higher speed.

For example, Patent Literature (PTL) 1 discloses a vertical field-effect transistor (FET) including: a regrowth layer positioned to cover an opening provided in a GaN-based laminate body; and a gate electrode positioned on and along the regrowth layer. A channel is formed by a two-dimensional electron gas (2DEG) generated in the regrowth layer. In general, vertical FETs are suitable for high-current operation as compared to lateral FETs. Vertical FETs, however, are not suitable for high-speed switching because they have large gate-drain capacitance (feedback capacitance).

To perform high-current operation and high-speed switching, Non-Patent Literature (NPL) 1 discloses a configuration in which a vertical FET formed using a SiC material and a low-breakdown-voltage lateral FET formed using a GaN material are connected in cascode. With this configuration, the switching speed is mainly determined by the low-breakdown-voltage lateral FET, thus enabling high-speed switching.

Although current flows through both the vertical FET and the low-breakdown-voltage lateral FET, high-current operation can be easily performed if the lateral FET is also designed for low breakdown voltage. Therefore, the device having a cascode connection can perform high-current operation. As described above, since the high-current vertical FET and the low-breakdown-voltage lateral FET are connected in cascode, high-speed switching and high-current operation can be both achieved.

### CITATION LIST

### Patent Literature

PTL 1: Japanese Patent No. 6511645

### Non Patent Literature

NPL 1: G. Lyu. et al., “A Normally-OFF Copackaged SiC-JFET/GaN-HEMT Cascode Device for High-Voltage and High-Frequency Applications”, IEEE TRANSACTIONS ON POWER ELECTRONICS, VOL. 35, NO. 9, September 2020, pp. 9669-9679

### SUMMARY

### Technical Problem

According to the configuration disclosed in NPL 1, since the vertical FET and the lateral FET are formed using different materials, it is necessary to fabricate each FET individually, and electrically connect them during mounting. As a result, a large parasitic inductance is generated between the vertical FET and the lateral FET, and stable operation becomes difficult during high-speed operation due to the influence of the parasitic inductance. Although the parasitic inductance can be reduced to some extent by mounting the vertical FET and the lateral FET in close proximity, it is advantageous for the parasitic inductance to be as small as possible in order to achieve stable operation under all operating conditions.

In view of this, the present disclosure provides a nitride semiconductor device capable of achieving high-current operation and high-speed switching with stability.

### Solution to Problem

A nitride semiconductor device according to an aspect of the present disclosure is a nitride semiconductor device including: a substrate; a channel layer provided above the substrate and including a nitride semiconductor as a main component; a vertical transistor provided in a first region in a plan view of the substrate, the vertical transistor being a normally-on transistor; and a lateral transistor provided in a second region different from the first region in the plan view of the substrate, the lateral transistor being a normally-off transistor, in which the vertical transistor includes: a first portion that is a portion of the channel layer and overlaps the first region in the plan view of the substrate; a first gate electrode provided above the first portion; and a first drain electrode provided below the substrate, the lateral transistor includes: a second portion that is a portion of the channel layer and overlaps the second region in the plan view of the substrate; a second gate electrode provided above the second portion; and a second source electrode provided above the substrate, the first gate electrode and the second source electrode are electrically connected to each other, and a source potential of the vertical transistor and a drain potential of the lateral transistor are equal.

### Advantageous Effects

According to the present disclosure, it is possible to achieve high-current operation and high-speed switching with stability.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is a cross-sectional view of a nitride semiconductor device according to Embodiment 1.

FIG. 2 is a circuit diagram of a nitride semiconductor device according to Embodiment 1.

FIG. 3 is a plan view of a nitride semiconductor device according to Embodiment 1.

FIG. 4 is a cross-sectional view of a nitride semiconductor device according to Variation 1 of Embodiment 1.

FIG. 5 is a cross-sectional view of a nitride semiconductor device according to Variation 2 of Embodiment 1.

FIG. 6 is a cross-sectional view of a nitride semiconductor device according to Variation 3 of Embodiment 1.

FIG. 7 is a cross-sectional view of a nitride semiconductor device according to Variation 4 of Embodiment 1.

FIG. 8 is a circuit diagram of a nitride semiconductor device according to Variation 5 of Embodiment 1.

FIG. 9 is a cross-sectional view of a nitride semiconductor device according to Variation 5 of Embodiment 1.

FIG. 10 is a plan view of a nitride semiconductor device according to Variation 5 of Embodiment 1.

FIG. 11 is a plan view of a nitride semiconductor device according to Embodiment 2.

FIG. 12 is a cross-sectional view of a nitride semiconductor device according to Embodiment 2.

FIG. 13 is a cross-sectional view of a nitride semiconductor device according to Variation 1 of Embodiment 2.

FIG. 14 is a cross-sectional view of a nitride semiconductor device according to Variation 2 of Embodiment 2.

### DESCRIPTION OF EMBODIMENTS

### Overview of the Present Disclosure

A nitride semiconductor device according to a first aspect of the present disclosure is a nitride semiconductor device including: a substrate; a channel layer provided above the substrate and including a nitride semiconductor as a main component; a vertical transistor provided in a first region in a plan view of the substrate, the vertical transistor being a normally-on transistor; and a lateral transistor provided in a second region different from the first region in the plan view of the substrate, the lateral transistor being a normally-off transistor, in which the vertical transistor includes: a first portion that is a portion of the channel layer and overlaps the first region in the plan view of the substrate; a first gate electrode provided above the first portion; and a first drain electrode provided below the substrate, the lateral transistor includes: a second portion that is a portion of the channel layer and overlaps the second region in the plan view of the substrate; a second gate electrode provided above the second portion; and a second source electrode provided above the substrate, the first gate electrode and the second source electrode are electrically connected to each other, and a source potential of the vertical transistor and a drain potential of the lateral transistor are equal.

Accordingly, since the cascode-connected vertical transistor and lateral transistor can be provided on the same substrate, it is possible to suppress the parasitic inductance in the interconnect wiring between the vertical transistor and the lateral transistor. Therefore, the nitride semiconductor device according to the present aspect is capable of achieving high-current operation and high-speed switching with stability.

A nitride semiconductor device according to a second aspect of the present disclosure is the nitride semiconductor device according to the first aspect, further including: a first nitride semiconductor layer that is of a first conductivity type and is provided between the substrate and the channel layer; and a second nitride semiconductor layer that is of a second conductivity type and is provided between the first nitride semiconductor layer and the channel layer, the second conductivity type having a polarity opposite to a polarity of the first conductivity type.

This makes it possible to suppress leak current flowing between the first drain electrode and the second source electrode. In addition, the breakdown voltage of the vertical transistor can be increased by a depletion layer formed by a p-n junction between the first nitride semiconductor layer and the second nitride semiconductor layer.

A nitride semiconductor device according to a third aspect of the present disclosure is the nitride semiconductor device according to the second aspect, in which the vertical transistor further includes a first source electrode set to the source potential, and the lateral transistor further includes a second drain electrode set to the drain potential.

Accordingly, for example, by using a highly conductive material as the electrode material, the vertical transistor and the lateral transistor can be connected with low resistance, thereby enabling reduction of the on-resistance of the nitride semiconductor device.

A nitride semiconductor device according to a fourth aspect of the present disclosure is the nitride semiconductor device according to the third aspect, in which, of the second nitride semiconductor layer, a portion overlapping the first region and a portion overlapping the second region in the plan view of the substrate are electrically isolated from each other.

Accordingly, when a predetermined potential is applied to the second nitride semiconductor layer, different potentials can be applied to the vertical transistor and the lateral transistor. It becomes possible to apply potentials suitable for achieving each feature of the vertical transistor having a high breakdown voltage and the lateral transistor capable of high-speed operation with a low breakdown voltage.

A nitride semiconductor device according to a fifth aspect of the present disclosure is the nitride semiconductor device according to the fourth aspect, in which, of the second nitride semiconductor layer, the portion overlapping the second region in the plan view of the substrate is electrically connected to the second source electrode.

Accordingly, since the second nitride semiconductor layer set to the source potential of the lateral transistor is disposed between the second gate electrode and the first drain electrode, it is possible to suppress leak current flowing from the first drain electrode of the vertical transistor to each electrode of the lateral transistor.

A nitride semiconductor device according to a sixth aspect of the present disclosure is the nitride semiconductor device according to the fourth or fifth aspect, in which, of the second nitride semiconductor layer, the portion overlapping the first region in the plan view of the substrate is electrically connected to the first source electrode.

Accordingly, since the second nitride semiconductor layer set to the source potential of the vertical transistor is disposed between the first gate electrode and the first drain electrode, the electric field strength applied between the gate and the drain can be attenuated, thereby enabling further increase in the breakdown voltage of the vertical transistor.

A nitride semiconductor device according to a seventh aspect of the present disclosure is the nitride semiconductor device according to the fourth or fifth aspect, in which, of the second nitride semiconductor layer, the portion overlapping the first region in the plan view of the substrate is electrically connected to the first gate electrode.

Accordingly, since the second nitride semiconductor layer set to the gate potential of the vertical transistor is disposed between the first source electrode and the first drain electrode, the drain-source capacitance of the vertical transistor can be made small. Accordingly, since the source potential of the vertical transistor and the drain potential of the lateral transistor can be made low, switching can be performed at higher speed.

A nitride semiconductor device according to an eighth aspect of the present disclosure is the nitride semiconductor device according to any one of the first through seventh aspects, in which the channel layer includes a laminated structure of a gallium nitride (GaN) layer and an aluminum gallium nitride (AlGaN) layer.

Accordingly, since a two-dimensional electron gas generated in the vicinity of a hetero-interface between GaN and AlGaN can be used as a current path, it is possible to implement a nitride semiconductor device suitable for high power and/or high-speed switching.

A nitride semiconductor device according to a ninth aspect of the present disclosure is the nitride semiconductor device according to any one of the first through eighth aspects, further including: one of an insulating layer or a third nitride semiconductor layer of a second conductivity type, the one of the insulating layer or the third nitride semiconductor layer being provided between the first gate electrode and the first portion, the second conductivity type having a polarity opposite to a polarity of a first conductivity type.

Accordingly, the threshold voltage of the vertical transistor can be adjusted according to, for example, the thickness or material of the third nitride semiconductor layer or the insulating layer. For example, a normally-on vertical transistor can be easily implemented.

A nitride semiconductor device according to a tenth aspect of the present disclosure is the nitride semiconductor device according to any one of the first through ninth aspects, further including: a fourth nitride semiconductor layer that is of a second conductivity type and is provided between the second gate electrode and the second portion, the second conductivity type having a polarity opposite to a polarity of a first conductivity type.

Accordingly, the threshold voltage of the lateral transistor can be adjusted according to, for example, the thickness or material of the fourth nitride semiconductor layer or the insulating layer. For example, a normally-off lateral transistor can be easily implemented.

A nitride semiconductor device according to an eleventh aspect of the present disclosure is the nitride semiconductor device according to any one of the first through tenth aspects, in which the second portion includes an impurity region provided in a range overlapping the second gate electrode in the plan view of the substrate, and the second gate electrode is electrically connected to the impurity region.

Accordingly, the threshold voltage of the vertical transistor can be adjusted according to, for example, the thickness or impurity material of the impurity region. For example, a normally-off lateral transistor can be easily implemented.

A nitride semiconductor device according to a twelfth aspect of the present disclosure is the nitride semiconductor device according to any one of the third through seventh aspects, further including: source wiring electrically connected to the second source electrode; and drain wiring electrically connected to the second drain electrode, in which the source wiring and the drain wiring partially overlap each other in the plan view of the substrate.

Accordingly, the drain-source capacitance of the lateral transistor can be increased. Therefore, since the drain potential of the lateral transistor can be made low, switching can be performed at higher speed.

A nitride semiconductor device according to a thirteenth aspect of the present disclosure is the nitride semiconductor device according to any one of the third through seventh aspects, further including: a PN diode including (i) an electrode connected to the second drain electrode and (ii) a fifth nitride semiconductor layer that is of the second conductivity type and is provided between the electrode and the channel layer.

Accordingly, the intermediate potential at the connection point between the vertical transistor and the lateral transistor can be set to a desired value. In addition, since the lateral transistor can be configured to avoid application of a voltage greater than or equal to a threshold voltage of the PN diode, the breakdown voltage of the lateral transistor can be lowered and switching can be performed at higher speed.

A nitride semiconductor device according to a fourteenth aspect of the present disclosure is the nitride semiconductor device according to the thirteenth aspect, further including: a plurality of PN diodes each of which is the PN diode, in which the plurality of PN diodes are connected in series.

Accordingly, the intermediate potential can be adjusted according to the total number of PN diodes connected in series.

A nitride semiconductor device according to a fifteenth aspect of the present disclosure is the nitride semiconductor device according to any one of the first through fourteenth aspects, further including: a plurality of vertical transistors each of which is the vertical transistor; and a plurality of lateral transistors each of which is the lateral transistor, in which the plurality of vertical transistors are arranged adjacent to each other in a third region in the plan view of the substrate, and the plurality of lateral transistors are arranged adjacent to each other in a fourth region not overlapping the third region in the plan view of the substrate.

Accordingly, the plurality of vertical transistors can be collectively disposed and the plurality of lateral transistors can be collectively disposed. Collectively disposing the transistors of the same type enables, for example, easy setting of the layout of wiring that connects one another. By reducing unnecessary wiring, the parasitic inductance can be decreased, thereby enabling stable, high-speed switching.

A nitride semiconductor device according to a sixteenth aspect of the present disclosure is the nitride semiconductor device according to any one of the first through fourteenth aspects, further including: a plurality of vertical transistors each of which is the vertical transistor; and a plurality of lateral transistors each of which is the lateral transistor, in which the plurality of vertical transistors and the plurality of lateral transistors are alternately arranged in the plan view of the substrate.

Since this enhances the area efficiency, the nitride semiconductor device can be downsized. In addition, since the region directly below the lateral transistor can be used as the current path for the drain current of the vertical transistor, the on-resistance of the nitride semiconductor device can be reduced.

A nitride semiconductor device according to a seventeenth aspect of the present disclosure is the nitride semiconductor device according to the second or third aspect, in which, of the second nitride semiconductor layer, a portion overlapping the second region in the plan view of the substrate is electrically connected to the second source electrode, and of the second nitride semiconductor layer, a portion overlapping the first region and the portion overlapping the second region in the plan view of the substrate are not electrically isolated from each other.

Accordingly, the potential of the second nitride semiconductor layer of the vertical transistor can be fixed to the gate potential of the vertical transistor even if the source electrode of the vertical transistor and the drain electrode of the lateral transistor are not provided. Therefore, since the drain-source capacitance of the vertical transistor can be made small, switching can be performed at higher speed. In addition, since the area efficiency is enhanced, the nitride semiconductor device can be downsized.

Hereinafter, exemplary embodiments will be specifically described with reference to the accompanying drawings.

Note that each of the embodiments described below shows a general or specific example. The numerical values, shapes, materials, constituent elements, the arrangement and connection of the constituent elements, steps, the processing order of the steps etc. shown in the following embodiments are mere examples, and therefore do not limit the scope of the present disclosure. Among the constituent elements in the following embodiments, those not recited in any one of the independent claims will be described as optional constituent elements.

Note also that the drawings are represented schematically and are not necessarily precise illustrations. Thus, the scales of the drawings, for example, are not necessarily precise. In the drawings, essentially the same constituent elements share the same reference signs, and redundant descriptions will be omitted or simplified.

Also, in the present specification, terms indicating a relationship between elements, such as “parallel” and “perpendicular”, terms that indicate the shapes of elements such as “rectangular” and “trapezoid”, and numerical value ranges do not express their strict meanings only, but also include substantially equivalent ranges, e.g., differences of several percent, as well.

In addition, the side of the substrate on which the gate electrode and the source electrode are provided is regarded as “above” or the “upper side”, whereas the side of the substrate on which the drain electrode of the vertical FET is provided is regarded as “below” or the “lower side”.

Note that, in the present specification, the terms “above”, “below”, and “lower part” do not indicate the up direction (vertically up) and the down direction (vertically down) in terms of the absolute spatial recognition, but are used as terms defined by a relative positional relationship based on the layering order in the laminated structure. In addition, the terms “above” and “below” are used not only when a constituent element is present between two other constituent elements spaced apart from each other, but also when two constituent elements are disposed in close contact with each other and touch each other.

Also, in the present specification, a “plan view” refers to a view in a direction perpendicular to a main surface of the substrate of the nitride semiconductor device, that is, a view of a main surface of the substrate as seen in a direction perpendicular to that surface.

Further, in the present specification, ordinal numerals such as “first” and “second” do not mean the number or order of constituent elements, unless otherwise stated in particular. The ordinal numerals are used to avoid confusion of and distinguish between constituent elements of the same type.

Furthermore, in the present specification, AlGaN refers to a ternary solid solution AlₓGa₁₋ₓN (0<x<1). Hereinafter, multicomponent solid solutions are abbreviated using the sequence of their constituent element symbols, such as AlInN and GaInN. For instance, AlₓGa_{1-x-y}In_{y}N (0<x<1, 0<y<1, and 0<x+y<1), which is an example of a nitride semiconductor, is abbreviated to AlGaInN.

### Embodiment 1

### Overview

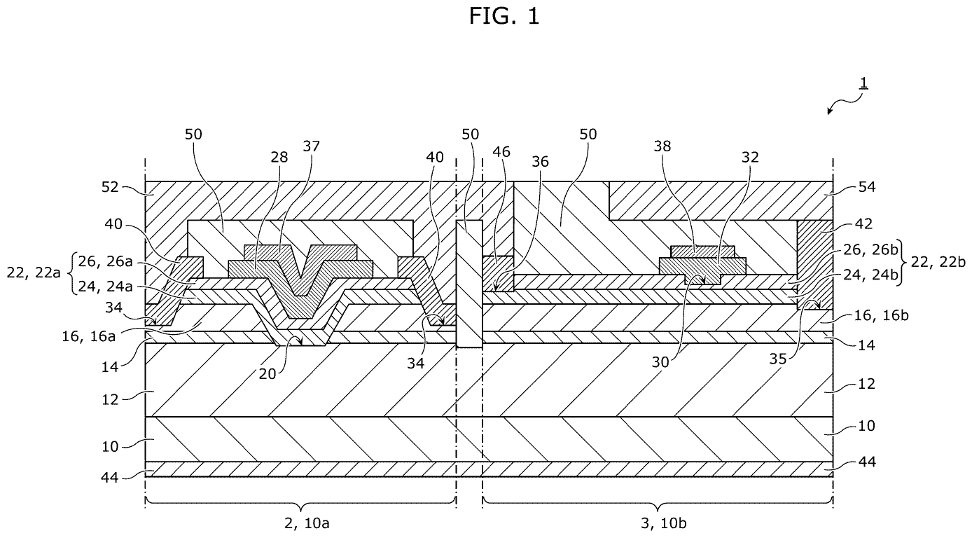

A nitride semiconductor device according to Embodiment 1 will be described with reference to FIG. 1. FIG. 1 is a cross-sectional view of nitride semiconductor device 1 according to the present embodiment.

Nitride semiconductor device 1 is a device having a laminated structure of semiconductor layers including a nitride semiconductor such as GaN as the main component. Although nitride semiconductor layers are typically formed by metalorganic vapor-phase epitaxy (MOVPE), they can be formed using other methods such as hydride vapor phase epitaxy (HVPE).

As illustrated in FIG. 1, nitride semiconductor device 1 includes vertical GaN transistor 2 and lateral GaN transistor 3 that are formed on the same substrate. Vertical GaN transistor 2 and lateral GaN transistor 3 are provided in regions different from each other in the plan view of the substrate.

Vertical GaN transistor 2 is an example of a vertical transistor that includes a semiconductor layer containing a nitride semiconductor as the main component. The vertical transistor is a transistor capable of conducting current mainly in a direction perpendicular to the main surfaces of the substrate. Vertical GaN transistor 2 is a normally-on transistor.

Lateral GaN transistor 3 is an example of a lateral transistor that includes a semiconductor layer containing a nitride semiconductor as the main component. The lateral transistor is a transistor capable of conducting current mainly in a direction parallel to the main surfaces of the substrate. Lateral GaN transistor 3 is a normally-off transistor.

For example, nitride semiconductor device 1 includes at least substrate 10 having n-type conductivity, drift layer 12 including n-type GaN, current block layer 16 including p-type GaN, electron transport layer 24 including GaN, and electron supply layer 26 including AlGaN. A two-dimensional electron gas (2DEG) is induced in the vicinity of the interface between electron supply layer 26 and electron transport layer 24, and functions as a current path. In addition, in the example illustrated in FIG. 1, high-resistance layer 14 that is highly doped with carbon (C), for instance, is provided below current block layer 16. Accordingly, leak current between current block layer 16 and substrate 10 can be reduced. Note that high-resistance layer 14 need not be provided.

In vertical GaN transistor 2, gate opening portion 20 is provided by completely removing a portion of current block layer 16 and a portion of high-resistance layer 14 to expose drift layer 12. Channel layer 22 and gate layer 28 that includes p-type GaN are provided to cover gate opening portion 20. Source opening portion 34 is provided by removing a portion of channel layer 22 to expose current block layer 16. Source electrode 40 is provided in contact with channel layer 22 exposed to the side surface of source opening portion 34 and current block layer 16 exposed to the bottom surface of source opening portion 34. Gate electrode 37 is provided in contact with gate layer 28. Drain electrode 44 is provided in contact with the lower surface of substrate 10.

In vertical GaN transistor 2, drain current flows from drain electrode 44 to source electrode 40 through substrate 10, drift layer 12, and channel layer 22. Note that vertical GaN transistor 2 has a normally-on characteristic, that is, current flows through vertical GaN transistor 2 even when gate voltage is 0 V. The threshold voltage of vertical GaN transistor 2 is minus 5 V, for example. Vertical GaN transistor 2 performs switching operation in which: drain current flows when the source potential and the gate potential are equal; and drain current does not flow when the gate potential is lower than the source potential by 5 V or greater.

In lateral GaN transistor 3, recess 30 is provided in electron supply layer 26, so electron supply layer 26 is partially thinned. Gate layer 32 including p-type GaN is provided on at least a portion of recess 30. Furthermore, gate electrode 38 is provided in contact with gate layer 32. Source electrode 42 and drain electrode 46 are provided to interpose gate electrode 38 therebetween. Source opening portion 35 is provided by removing a portion of channel layer 22 to expose current block layer 16. Source electrode 42 is provided to be in contact with channel layer 22 exposed to the side surface of source opening portion 35 and current block layer 16 exposed to the bottom surface of source opening portion 35. In addition, drain opening portion 36 is provided by removing a portion of electron supply layer 26 to expose electron transport layer 24. Drain electrode 46 is provided in contact with electron transport layer 24 at the bottom surface of drain opening portion 36. Note that drain opening portion 36 need not be provided and drain electrode 46 may be provided on the upper surface of electron supply layer 26. Current block layer 16 and drain electrode 46 are electrically isolated from each other by electron transport layer 24. In addition, field plate 54 electrically connected to source electrode 42 is formed to cover gate layer 32 and gate electrode 38. Accordingly, the electric field strength applied to the gate end can be attenuated. However, when the electric field strength applied to the gate end is small, field plate 54 need not be provided.

In lateral GaN transistor 3, drain current flows from drain electrode 46 to source electrode 42 through channel layer 22. Lateral GaN transistor 3 has a normally-off characteristic, that is, drain current does not flow when the gate potential and the source potential are equal. The threshold voltage of lateral GaN transistor 3 is higher than the threshold voltage of vertical GaN transistor 2, and is 2 V, for example. Lateral GaN transistor 3 performs switching operation in which: drain current does not flow when the gate potential is 0 V with respect to the source potential 0 V; and drain current flows when the gate potential is 2 V or greater.

### [Cross-Sectional Configuration]

Next, a specific cross-sectional configuration of nitride semiconductor device 1 will be described.

As illustrated in FIG. 1, nitride semiconductor device 1 includes substrate 10, drift layer 12, high-resistance layer 14, current block layer 16, channel layer 22, gate layers 28 and 32, gate electrodes 37 and 38, source electrodes 40 and 42, drain electrodes 44 and 46, insulating film 50, wiring electrode 52, and field plate 54. Channel layer 22 includes electron transport layer 24 and electron supply layer 26. In addition, gate opening portion 20, source opening portions 34 and 35, and drain opening portion 36 are provided in nitride semiconductor device 1.

Note that in the present embodiment, substrate 10, drift layer 12, high-resistance layer 14, current block layer 16, channel layer 22, and drain electrode 44 are provided to extend across first region 10a and second region 10b. First region 10a and second region 10b are regions different from each other in the plan view of substrate 10.

First region 10a is the region in which vertical GaN transistor 2 is provided. Specifically, first region 10a includes two source electrodes 40 disposed to interpose gate electrode 37 therebetween, and can be regarded as the region between the two source electrodes 40, both inclusive. Second region 10b is the region in which lateral GaN transistor 3 is provided. Specifically, second region 10b includes source electrode 42 and drain electrode 46, and can be regarded as the region between these electrodes, both inclusive. For example, as illustrated in FIG. 1, current block layer 16, channel layer 22, electron transport layer 24, and electron supply layer 26 respectively include first portions 16a, 22a, 24a, and 26a overlapping first region 10a and second portions 16b, 22b, 24b, and 26b overlapping second region 10b.

Vertical GaN transistor 2 includes first portion 22a that is a portion of channel layer 22. Specifically, vertical GaN transistor 2 includes a laminated structure of: first portion 24a that is a portion of electron transport layer 24; and first portion 26a that is a portion of electron supply layer 26. Vertical GaN transistor 2 also includes first portion 16a that is a portion of current block layer 16. Vertical GaN transistor 2 further includes a portion of substrate 10, a portion of drift layer 12, gate layer 28, gate electrode 37, source electrodes 40, and drain electrode 44.

Lateral GaN transistor 3 includes second portion 22b that is a portion of channel layer 22. Specifically, lateral GaN transistor 3 includes a laminated structure of: second portion 24b that is a portion of electron transport layer 24; and second portion 26b that is a portion of electron supply layer 26. Lateral GaN transistor 3 also includes second portion 16b that is a portion of current block layer 16. Lateral GaN transistor 3 further includes gate layer 32, gate electrode 38, source electrode 42, and drain electrode 46.

In the present embodiment, nitride semiconductor device 1 includes wiring electrode 52 that connects source electrodes 40 of vertical GaN transistor 2 and drain electrode 46 of lateral GaN transistor 3. Insulating film 50 is provided between (i) wiring electrode 52 and (ii) gate electrode 37 and gate layer 28 of vertical GaN transistor 2 and between (iii) field plate 54 and (iv) gate electrode 38 and gate layer 32 of lateral GaN transistor 3. Insulating film 50 is provided to electrically isolate current block layer 16 and channel layer 22 of vertical GaN transistor 2 from current block layer 16 and channel layer 22 of lateral GaN transistor 3.

Hereinafter, the details of each constituent element included in nitride semiconductor device 1 will be described.

Substrate 10 is a substrate including a nitride semiconductor and includes two main surfaces, an upper surface and a lower surface that face away from each other as illustrated in FIG. 1. The upper surface is the surface on the side where drift layer 12 is provided. Specifically, the upper surface is substantially identical to the c-plane. The lower surface is also called the back surface and is the surface on the side where drain electrode 44 is provided.

Substrate 10, for example, has a thickness of 300 μm and includes n-type GaN having a carrier concentration of 1×10¹⁸ cm⁻³. Note that substrate 10 need not be a nitride semiconductor substrate so long as it is electrically conductive. For example, substrate 10 may be a silicon (Si) substrate, a carbide silicon (SiC) substrate, or the like.

Note that the n-type is an example of the first conductivity type. The state in which the n-type impurity concentration is high, commonly referred to as a heavily doped state, is called n⁺-type, whereas the state in which the n-type impurity concentration is low, commonly referred to as a lightly doped state, is called n⁻-type. The n⁺-type and the n⁻-type are also examples of the first conductivity type. The p-type is an example of the second conductivity type having a polarity opposite to that of the first conductivity type. The state in which the p-type impurity concentration is high, commonly referred to as a heavily doped state, is called p⁺-type, whereas the state in which the p-type impurity concentration is low, commonly referred to as a lightly doped state, is called p⁻-type. The p⁺-type and the p⁻-type are also examples of the second conductivity type.

Drift layer 12 is an example of the first nitride semiconductor layer of the first conductivity type, and is specifically a nitride semiconductor layer that is of the same conductivity type as substrate 10 and is provided above substrate 10. Drift layer 12 is provided between substrate 10 and channel layer 22. The carrier concentration and thickness of drift layer 12 are important parameters that determine the breakdown voltage of nitride semiconductor device 1, and are adjusted according to the operating voltage. For instance, when the rated voltage is 650 V, an n-type GaN layer having a thickness of 8 μm and a carrier concentration of 1×10¹⁶ cm⁻³, for example, is provided as drift layer 12. Note that Si can be typically used as an impurity that exhibits the n-type conductivity. Drift layer 12 is provided in contact with the upper surface of substrate 10, for example.

High-resistance layer 14 is provided between drift layer 12 and current block layer 16. High-resistance layer 14 is a GaN or AlGaN layer doped with carbon (C) at high concentration, but is not limited thereto. High-resistance layer 14 is provided in contact with the upper surface of drift layer 12.

Current block layer 16 is an example of the second nitride semiconductor layer of the second conductivity type, and is specifically a layer that includes p-type GaN and is provided above drift layer 12. Current block layer 16 is provided between drift layer 12 and channel layer 22. In the present embodiment, current block layer 16 is provided in contact with the upper surface of high-resistance layer 14. Current block layer 16 has, for example, a thickness of 300 nm and a carrier concentration of 1×10¹⁷ cm⁻³. Note that Mg can be typically used as an impurity that exhibits the p-type conductivity. Note that current block layer 16 may be formed of a plurality of layers including at least a p-type semiconductor layer.

In vertical GaN transistor 2, gate opening portion 20 that passes through current block layer 16 and high-resistance layer 14 to expose drift layer 12 is provided. The side surface of gate opening portion 20 is inclined relative to the bottom surface of gate opening portion 20, but may be perpendicular to the bottom surface of gate opening portion 20. Drain current flows from drift layer 12 to channel layer 22 through the bottom surface of gate opening portion 20.

Channel layer 22 is provided to cover the inner surface of gate opening portion 20 and the upper surface of current block layer 16. Specifically, electron transport layer 24 and electron supply layer 26 are provided in the stated order. Electron transport layer 24 and electron supply layer 26 are in contact with each other. Typically, electron supply layer 26 is an AlGaN layer and electron transport layer 24 is a GaN layer. Each of electron supply layer 26 and electron transport layer 24 is an undoped layer that is not intentionally doped with impurities. Note that the term “undoped” means that a dopant, such as Si or Mg, that changes the polarity of GaN to n-type or p-type is not introduced, but also includes the case where an extremely small amount of dopant that does not contribute to electrical conductivity is introduced. At a hetero-interface between electron supply layer 26 and electron transport layer 24, a highly concentrated 2DEG is generated by spontaneous polarization or piezoelectric polarization at the (0001) plane. The 2DEG is a layer having a high electron mobility, and this layer functions as a channel below the gate.

The concentration of the 2DEG is determined by, for example, the AI composition and thickness of AlGaN included in electron supply layer 26. The threshold voltage of vertical GaN transistor 2 is adjustable according to the concentration of the 2DEG. For example, the threshold voltage of vertical GaN transistor 2 shifts toward a positive value as the thickness of electron supply layer 26 is smaller. Electron supply layer 26 of vertical GaN transistor 2 according to the present embodiment has an AI composition ratio of 20% and a thickness of 50 nm, for example. In this case, the threshold voltage of vertical GaN transistor 2 is negative, and vertical GaN transistor 2 is a transistor having a normally-on characteristic.

Note that, of the electron supply layer of lateral GaN transistor 3, that is, of second portion 26b of electron supply layer 26, the portion where recess 30 is not provided is formed concurrently with the electron supply layer of vertical GaN transistor 2, that is, first portion 26a of electron supply layer 26. Therefore, second portion 26b has the same AI composition ratio and the same thickness as first portion 26a, that is, the AI composition ratio of 20% and the thickness of 50 nm. However, recess 30 is provided in at least a portion of the region below gate electrode 38 of lateral GaN transistor 3, thereby thinning electron supply layer 26 to 20 nm, for example. Accordingly, lateral GaN transistor 3 achieves the normally-off characteristic.

Channel layer 22 is formed by regrowth of the crystal of a nitride semiconductor such as GaN and AlGaN, after gate opening portion 20 is formed. By removing portions of the laminated structure of GaN and AlGaN formed by the crystal regrowth, it is possible to form source opening portions 34 and 35 and drain opening portion 36.

Gate opening portion 20, source opening portions 34 and 35, and drain opening portion 36 are each formed by removing a portion of a nitride semiconductor film formed by crystal growth. For example, dry etching such as inductively coupled plasma (ICP) etching can be used as a method for removing a portion of current block layer 16, electron transport layer 24, and electron supply layer 26. For example, a chlorine-based gas can be used as the process gas for the dry etching.

Gate layer 28 is an example of the third nitride semiconductor layer of the second conductivity type, and is provided between gate electrode 37 and first portion 22a of channel layer 22. Gate layer 28, for example, includes p-type GaN and is provided in contact with first portion 26a of electron supply layer 26 to cover gate opening portion 20.

Gate layer 32 is an example of the fourth nitride semiconductor layer of the second conductivity type, and is provided between gate electrode 38 and second portion 22b of channel layer 22. Gate layer 32, for example, includes p-type GaN and is provided in contact with second portion 26b of electron supply layer 26 to cover recess 30.

Gate layers 28 and 32 can be concurrently formed by crystal growth of a nitride semiconductor. In doing so, Mg can be used as an impurity that exhibits the p-type conductivity. For example, after recess 30 is formed, a p-type GaN film is formed to cover electron supply layer 26 by epitaxial growth while introducing a p-type impurity. By patterning the formed p-type GaN film to separate into first region 10a and second region 10b, gate layers 28 and 32 can be concurrently formed. Accordingly, gate layers 28 and 32 can have the same composition, impurity concentration, and thickness, for example.

Note that gate layers 28 and 32 may be formed by different processes. For example, electron transport layer 24, electron supply layer 26, and gate layer 28 are formed by continuous crystal growth, and after that, when gate layer 28 is patterned, the p-type GaN film (gate layer 32) provided in second region 10b is also removed. Subsequently, after recess 30 is formed, gate layer 32 may be formed in second region 10b by crystal regrowth and patterning. In this case, since gate layers 28 and 32 can have different compositions, impurity concentrations, and thicknesses, for example, it is possible to form gate layers 28 and 32 suitable for achieving each of the normally-on characteristic of vertical GaN transistor 2 and the normally-off characteristic of lateral GaN transistor 3, for instance. In addition, in vertical GaN transistor 2, since it is possible to suppress creation of an impurity level at the interface between gate layer 28 and channel layer 22, a favorable p-n junction is formed between gate layer 28 and channel layer 22 and the off characteristic can be enhanced.

Gate electrode 37 is an example of the first gate electrode and is provided above first portion 22a of channel layer 22. Specifically, gate electrode 37 is provided in contact with the upper surface of gate layer 28.

Gate electrode 38 is an example of the second gate electrode and is provided above second portion 22b of channel layer 22. Specifically, gate electrode 38 is provided in contact with the upper surface of gate layer 32.

Source electrode 40 is an example of the first source electrode and is provided above substrate 10 and apart from gate electrode 37 and gate layer 28. Specifically, source electrode 40 is provided along the inner surface of source opening portion 34. Source electrode 40 is in contact with first portion 16a of current block layer 16 and first portion 24a of electron transport layer 24.

Source electrode 42 is an example of the second source electrode and is provided above substrate 10 and apart from gate electrode 38 and gate layer 32. Specifically, source electrode 42 is provided along the inner surface of source opening portion 35. Source electrode 42 is in contact with second portion 16b of current block layer 16 and second portion 24b of electron transport layer 24.

Note that, as illustrated in FIG. 1, both source electrodes 40 and 42 are also in contact with electron supply layer 26; however, they need not be in contact with electron supply layer 26. In addition, source opening portions 34 and 35 need not be provided. In such a case, source electrodes 40 and 42 are provided apart from gate electrodes 37 and 38 and gate layers 28 and 32, respectively and in contact with the upper surface of electron supply layer 26.

Drain electrode 44 is an example of the first drain electrode and is provided below substrate 10. Drain electrode 44 is provided in contact with the entire lower surface of substrate 10, but is not limited thereto. For example, drain electrode 44 may be provided in a range overlapping first region 10a in plan view, and need not be provided in a range overlapping second region 10b in plan view.

Drain electrode 46 is an example of the second drain electrode and is provided above substrate 10 to interpose gate electrode 38 between drain electrode 46 and source electrode 42. Specifically, drain electrode 46 is provided along the inner surface of drain opening portion 36. Drain electrode 46 is in contact with second portion 24b of electron transport layer 24. Drain electrode 46 is also in contact with electron supply layer 26, but need not be in contact with electron supply layer 26. In addition, drain opening portion 36 need not be provided. In such a case, drain electrode 46 is provided in contact with the upper surface of electron supply layer 26.

Electron beam (EB) evaporation, sputtering, or the like can be used as the method for forming each electrode. After an electrically conductive film such as a metal film is formed, patterning is performed to make a predetermined shape by photolithography and wet etching or dry etching, for example. By doing so, each electrode can be formed. Gate electrodes 37 and 38 can be formed using a material that forms an ohmic contact with a p-type nitride semiconductor layer. For example, a Pd-based material is used. Source electrodes 40 and 42 and drain electrodes 44 and 46 can be formed using a material that forms an ohmic contact with an n-type nitride semiconductor layer. For example, a Ti/Al-based material is used.

Insulating film 50 is provided to protect the upper surface of each of vertical GaN transistor 2 and lateral GaN transistor 3. Specifically, insulating film 50 covers the upper surfaces of gate electrodes 37 and 38, gate layers 28 and 32, and channel layer 22. Insulating film 50 is formed using an insulating material such as a silicon oxide film or a silicon nitride film, for example. Openings are provided in insulating film 50 to expose a portion of each electrode. Through the openings, wiring electrode 52, field plate 54, and an electrode pad that are provided above insulating film 50 are connected to each electrode.

In the present embodiment, current block layer 16 is removed from the boundary between vertical GaN transistor 2 and lateral GaN transistor 3. Insulating film 50 is provided in the portion from which current block layer 16 has been removed. Accordingly, first portion 16a of current block layer 16 and second portion 16b of current block layer 16 are electrically isolated from each other.

Wiring electrode 52 is an example of the drain wiring and electrically connects source electrodes 40 of vertical GaN transistor 2 and drain electrode 46 of lateral GaN transistor 3. In addition, although not illustrated in FIG. 1, a wiring electrode that electrically connects source electrode 42 of lateral GaN transistor 3 and gate electrode 37 of vertical GaN transistor 2 is provided as an example of the source wiring.

Field plate 54 is a portion of the source wiring and is electrically connected to source electrode 42. Field plate 54 is provided to overlap gate electrode 38 and gate layer 32 in the plan view of substrate 10. Accordingly the electric field strength applied to the gate end can be attenuated.

Each wiring, such as wiring electrode 52 and field plate 54, is formed using an electrically conductive material such as metal. After an electrically conductive film is formed by EB evaporation, sputtering, or the like, patterning is performed to make a predetermined shape, thereby forming each wiring.

### [Circuit Configuration]

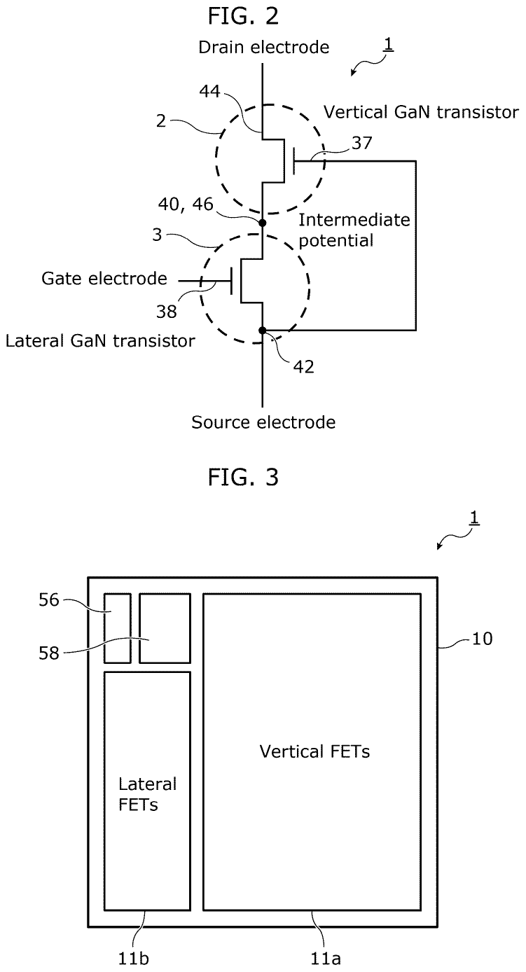

Next, circuit configurations of vertical GaN transistor 2 and lateral GaN transistor 3 will be described with reference to FIG. 2.

FIG. 2 is a circuit diagram of nitride semiconductor device 1 according to the present embodiment. As illustrated in FIG. 2, in nitride semiconductor device 1, a voltage (potential) is externally applied to drain electrode 44 of vertical GaN transistor 2 and each of source electrode 42 and gate electrode 38 of lateral GaN transistor 3. Accordingly, switching operation of nitride semiconductor device 1 is performed. Operation of nitride semiconductor device 1 will be described on the assumption that source electrode 40 of vertical GaN transistor 2 and drain electrode 46 of lateral GaN transistor 3 are electrically connected to each other and that the potential at source electrode 40 and drain electrode 46 is regarded as the intermediate potential. Note that the voltages described below are mere examples, and need not necessarily be the voltages described.

Nitride semiconductor device 1 is in the off state when a voltage of 0 V is applied to gate electrode 38 of lateral GaN transistor 3. That is to say, current does not flow between drain electrode 44 of vertical GaN transistor 2 and source electrode 42 of lateral GaN transistor 3. At this time, the voltage at drain electrode 44 of vertical GaN transistor 2 is a voltage set by the system, and is 400 V, for example. Since the voltage at source electrode 42 of lateral GaN transistor 3 is 0 V, the voltage at gate electrode 37 of vertical GaN transistor 2 electrically connected to source electrode 42 is also 0 V. The value of the intermediate potential is determined by the ratio of the drain-source capacitances of vertical GaN transistor 2 and lateral GaN transistor 3. Although the value of the intermediate potential can be designed as desired, it is 10 V, for example, in the present embodiment.

In this case, since a voltage of 390 V is applied between the drain and source of vertical GaN transistor 2 during OFF time, a relatively high-breakdown-voltage device is required as vertical GaN transistor 2. On the other hand, since only 10 V is applied between the drain and source of lateral GaN transistor 3, a low-breakdown-voltage device is sufficient as lateral GaN transistor 3. Note that since the threshold voltage of vertical GaN transistor 2 is −5 V, vertical GaN transistor 2 is in the off state when the intermediate potential is 10 V and the gate voltage of vertical GaN transistor 2 is 0 V.

Lateral GaN transistor 3 is turned on when a voltage of, for example, 5 V is applied to gate electrode 38 of lateral GaN transistor 3. Simultaneously, the intermediate potential becomes substantially 0 V, and thus, vertical GaN transistor 2 is turned on. As a result of the above, nitride semiconductor device 1 is turned on, and current flows between drain electrode 44 of vertical GaN transistor 2 and source electrode 42 of lateral GaN transistor 3. Since both vertical GaN transistor 2 and low-breakdown-voltage lateral GaN transistor 3 can conduct high current in a small area, high-current operation is possible. Also, since it is low-breakdown-voltage lateral GaN transistor 3 that controls ON/OFF of a switch in nitride semiconductor device 1, extremely high-speed switching is possible owing to the small gate-drain capacitance and the small Miller effect.

### [Planar Layout]

Next, an example of the planar layout of nitride semiconductor device 1 according to the present embodiment will be described with reference to FIG. 3.

FIG. 3 is a plan view of nitride semiconductor device 1 according to the present embodiment. In the present embodiment, as illustrated in FIG. 3, vertical GaN transistor 2 is provided in region 11a and lateral GaN transistor 3 is provided in region 11b in the plan view of substrate 10. Regions 11a and 11b are regions not overlapping each other in the plan view of substrate 10. Regions 11a and 11b are adjacent to each other.

Specifically, nitride semiconductor device 1 includes a plurality of vertical GaN transistors 2 and a plurality of lateral GaN transistors 3. The plurality of vertical GaN transistors 2 are provided side by side in region 11a. The plurality of lateral GaN transistors 3 are provided side by side in region 11b.

For example, in the plurality of vertical GaN transistors 2, gate electrodes 37 and source electrodes 40 are each in an elongated shape extending in the depth direction of the sheet of FIG. 1 illustrating the cross-sectional view. A plurality of gate electrodes 37 and a plurality of source electrodes 40 are alternately arranged in their short-side direction within region 11a. Two adjacent vertical GaN transistors 2 may share one source electrode 40. Note that such a shape and arrangement are a mere example, and the shape and arrangement of gate electrodes 37 and source electrodes 40 are not particularly limited.

In the plurality of lateral GaN transistors 3, gate electrodes 38, source electrodes 42, and drain electrodes 46 are each in an elongated shape extending in the depth direction of the sheet of FIG. 1 illustrating the cross-sectional view. A plurality of gate electrodes 38, a plurality of source electrodes 42, and a plurality of drain electrodes 46 are arranged within region 11b in the following manner repeatedly: Source electrodes 42 and drain electrodes 46 are alternately arranged in their short-side direction, and gate electrodes 38 are each disposed therebetween. Note that such a shape and arrangement are a mere example, and the shape and arrangement of gate electrodes 38, source electrodes 42, and drain electrodes 46 are not particularly limited.

As illustrated in FIG. 3, nitride semiconductor device 1 includes gate pad 56 and source pad 58. Gate pad 56 is a pad for receiving from outside a voltage that is applied to gate electrodes 38 of lateral GaN transistors 3. Source pad 58 is a pad for receiving from outside a voltage that is applied to source electrodes 42 of lateral GaN transistors 3.

In such a manner, vertical GaN transistors 2 and lateral GaN transistors 3 are provided on the same substrate 10. Therefore, vertical GaN transistors 2 and lateral GaN transistors 3 can be integrated in regions close to each other, and the wiring distance to each other can be shortened. Specifically, parasitic inductance between source electrodes 40 of vertical GaN transistors 2 and drain electrodes 46 of lateral GaN transistors 3 and parasitic inductance between source electrodes 42 of lateral GaN transistors 3 and gate electrodes 37 of vertical GaN transistors 2 can be made extremely small. Accordingly, occurrence of noise and misoperation is suppressed even if high-frequency operation is performed, and nitride semiconductor device 1 is therefore suitable for high-frequency switching.

As described above, nitride semiconductor device 1 according to the present embodiment is capable of achieving high-current operation and high-speed switching with stability.

Note that although vertical GaN transistor 2 and lateral GaN transistor 3 in the present embodiment each include a p-type nitride semiconductor layer as gate layer 28 or 32, the present disclosure is not limited thereto. So long as vertical GaN transistor 2 having the normally-on characteristic and lateral GaN transistor 3 having the normally-off characteristic can be implemented, it is acceptable to adopt a different gate structure such as a metal-insulator-semiconductor (MIS) structure in which a gate insulating film is used as gate layers 28 and 32. For example, as the gate insulating film, a silicon nitride film formed by plasma-enhanced chemical vapor deposition can be used.

### Variations of Embodiment 1

Next, a plurality of variations of Embodiment 1 will be described. The following description will focus on the points different from Embodiment 1 and will omit or simplify common points.

### Variation 1

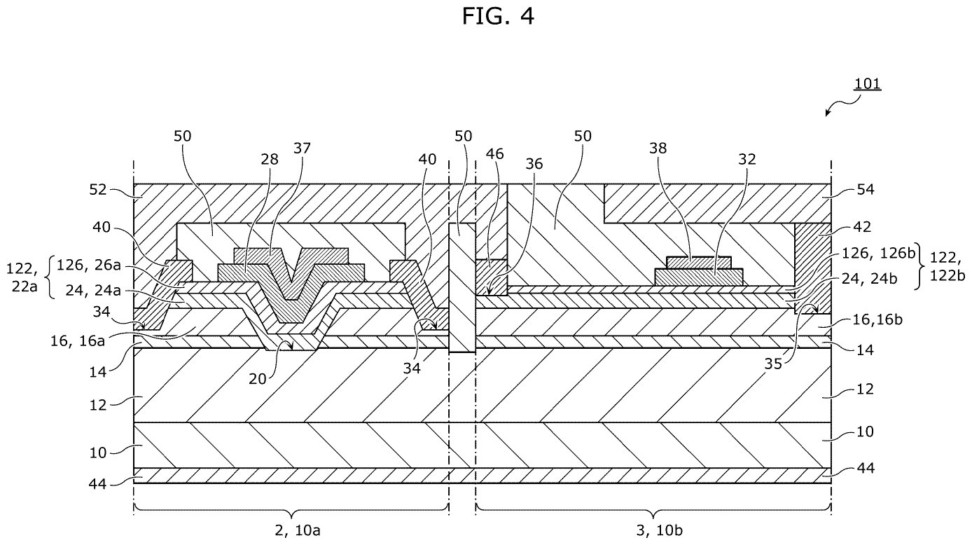

First, a nitride semiconductor device according to Variation 1 will be described with reference to FIG. 4.

FIG. 4 is a cross-sectional view of nitride semiconductor device 101 according to Variation 1 of the present embodiment. As compared to nitride semiconductor device 1 illustrated in FIG. 1, nitride semiconductor device 101 illustrated in FIG. 4 is different in that recess 30 is not provided in lateral GaN transistor 3. Nitride semiconductor device 101 is the same as nitride semiconductor device 1 in configuration of vertical GaN transistor 2.

As illustrated in FIG. 4, nitride semiconductor device 101 includes channel layer 122 instead of channel layer 22. Channel layer 122 includes electron transport layer 24 and electron supply layer 126. The configuration of second portion 122b of channel layer 122 is different from that of second portion 22b of channel layer 22 in Embodiment 1.

Specifically, in lateral GaN transistor 3, the thickness of electron supply layer 126, that is, the thickness of second portion 126b, is constant from an end portion of source electrode 42 to an end portion of drain electrode 46. Second portion 126b of electron supply layer 126 does not include recess 30, and therefore does not have a region below gate electrode 38 where electron supply layer 126 is partially thin.

Note that the thickness of second portion 126b of electron supply layer 126 is less than the thickness of first portion 26a to impart a normally-off characteristic to lateral GaN transistor 3. Typically, electron supply layer 126 of vertical GaN transistor 2 and electron supply layer 126 of lateral GaN transistor 3 are concurrently formed by crystal growth. Therefore, electron supply layer 126 of vertical GaN transistor 2 and electron supply layer 126 of lateral GaN transistor 3 have the same AI composition and the same thickness. In the present embodiment, the surface layer portion of second portion 126b is partially removed by, for example, dry etching after the crystal growth, thereby enabling reduction in the thickness of second portion 126b.

With this configuration, the gate length (the length in the lateral direction in the cross-sectional view) can be shortened, and it is thus possible to implement lateral GaN transistor 3 in a small area. Therefore, it is possible to downsize nitride semiconductor device 101. It is also possible to reduce the cost of nitride semiconductor device 101.

In the present variation, too, the advantageous effect in that nitride semiconductor device 101 is capable of achieving high-current operation and high-speed switching with stability remains unchanged. Nitride semiconductor device 101 has the advantage that the chip area thereof can be made small.

### Variation 2

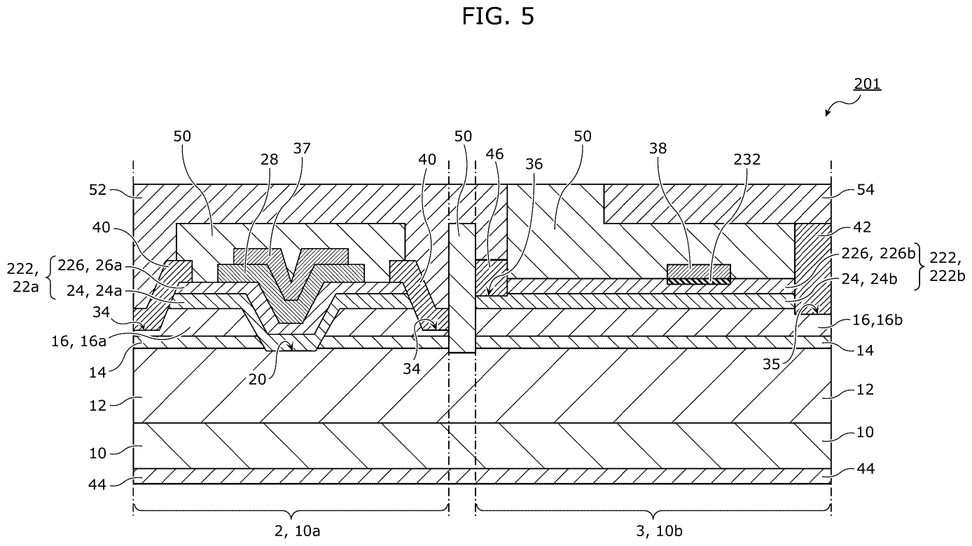

Next, a nitride semiconductor device according to Variation 2 will be described with reference to FIG. 5.

FIG. 5 is a cross-sectional view of nitride semiconductor device 201 according to Variation 2 of the present embodiment. As compared to nitride semiconductor device 1 illustrated in FIG. 1, nitride semiconductor device 201 illustrated in FIG. 5 is different in that, in lateral GaN transistor 3, impurity region 232 is provided instead of recess 30 and gate layer 32. Nitride semiconductor device 201 is the same as nitride semiconductor device 1 in configuration of vertical GaN transistor 2.

As illustrated in FIG. 5, nitride semiconductor device 201 includes channel layer 222 instead of channel layer 22. Channel layer 222 includes electron transport layer 24 and electron supply layer 226. The configuration of second portion 222b of channel layer 222 is different from that of second portion 22b of channel layer 22 in Embodiment 1. Specifically, impurity region 232 is provided in second portion 226b of electron supply layer 226.

Impurity region 232 is provided in a range overlapping gate electrode 38 in the plan view of substrate 10. Gate electrode 38 is connected to impurity region 232. Impurity region 232 is formed through, for example, ion implantation into the surface layer portion of second portion 226b of electron supply layer 226. For example, the atom implanted is Mg or F. Since the concentration of the 2DEG is small in impurity region 232, a normally-off characteristic can be easily imparted to lateral GaN transistor 3 even without gate layer 32 that includes p-type GaN and is illustrated in FIG. 1 and FIG. 4.

With this configuration, too, the gate length can be shortened, and it is thus possible to implement lateral GaN transistor 3 in a small area as in Variation 1 of Embodiment 1. Therefore, it is possible to downsize nitride semiconductor device 201. It is also possible to reduce the cost of nitride semiconductor device 201.

As described above, in the present variation, too, the advantageous effect in that nitride semiconductor device 201 is capable of achieving high-current operation and high-speed switching with stability remains unchanged. Moreover, nitride semiconductor device 201 has the advantage that the size and fabrication cost thereof can be reduced.

### Variation 3

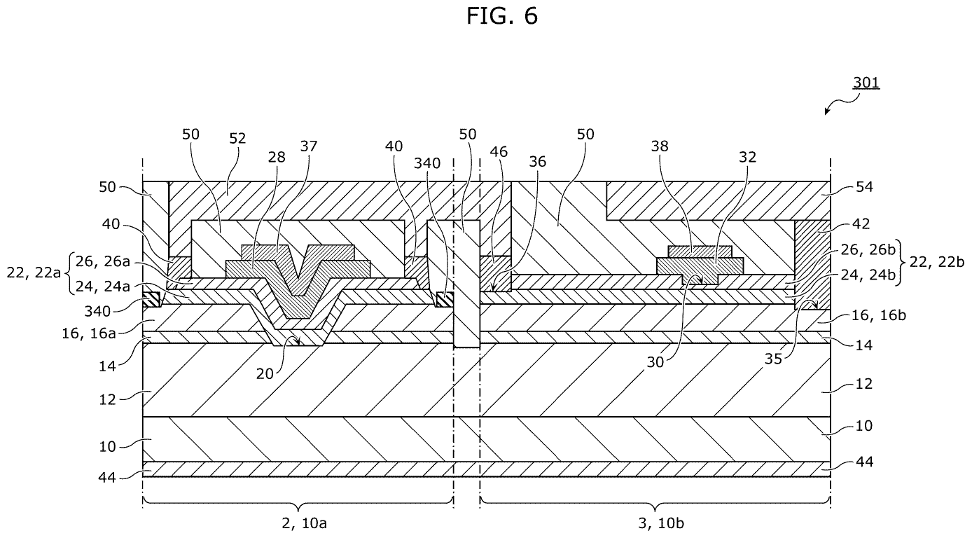

Next, a nitride semiconductor device according to Variation 3 will be described with reference to FIG. 6.

FIG. 6 is a cross-sectional view of nitride semiconductor device 301 according to Variation 3 of the present embodiment. As compared to nitride semiconductor device 1 illustrated in FIG. 1, nitride semiconductor device 301 illustrated in FIG. 6 is different in that vertical GaN transistor 2 includes potential fixing electrode 340. Nitride semiconductor device 301 is the same as nitride semiconductor device 1 in configuration of lateral GaN transistor 3. Note that in the present variation, first region 10a is regarded as the region between two potential fixing electrodes 340, both inclusive; however, first region 10a may be regarded as the region between two source electrodes 40, both inclusive, as in Embodiment 1 and the other variations.

Specifically, as illustrated in FIG. 6, potential fixing electrode 340 is provided in contact with current block layer 16 at the bottom surface of source opening portion 34. Potential fixing electrode 340 is electrically connected to gate electrode 37. Accordingly, the potential of current block layer 16 of vertical GaN transistor 2 (that is, first portion 16a) becomes equal to that of gate electrode 37 rather than source electrode 40.

Note that in the present variation, source electrode 40 is not in contact with first portion 16a of current block layer 16. Source electrode 40 and potential fixing electrode 340 are provided apart from each other to avoid contact.

In the circuit diagram illustrated in FIG. 2, in order to achieve higher-speed switching, it is advantageous to design the intermediate potential during OFF time to be as low as possible within the range in which vertical GaN transistor 2 can be turned off. To do so, the drain-source capacitance of vertical GaN transistor 2 needs to be small relative to the drain-source capacitance of lateral GaN transistor 3.

In the present variation, as viewed from drain electrode 44 of vertical GaN transistor 2, source electrode 40 is shielded by first portion 16a of current block layer 16 connected to potential fixing electrode 340. Therefore, the drain-source capacitance of vertical GaN transistor 2 can be made extremely small.

As described above, in the present variation, it is possible to use a low-breakdown-voltage lateral GaN transistor as lateral GaN transistor 3 by making the intermediate potential low. Therefore, nitride semiconductor device 301 provides the advantageous effect of enabling higher-speed switching.

### Variation 4

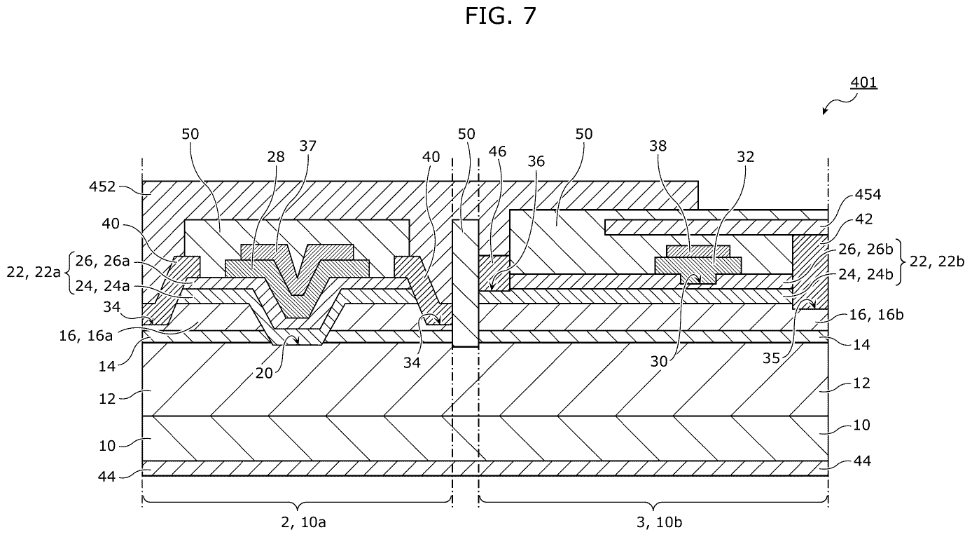

Next, a nitride semiconductor device according to Variation 4 will be described with reference to FIG. 7.

FIG. 7 is a cross-sectional view of nitride semiconductor device 401 according to Variation 4 of the present embodiment. As compared to nitride semiconductor device 1 illustrated in FIG. 1, nitride semiconductor device 401 illustrated in FIG. 7 is different in that wiring electrode 452 and field plate 454 are included instead of wiring electrode 52 and field plate 54. Wiring electrode 452 and field plate 454 are different from wiring electrode 52 and field plate 54 in that wiring electrode 452 and field plate 454 partially overlap each other in plan view.

Specifically, as illustrated in FIG. 7, wiring electrode 452 is provided to overlap field plate 454 in plan view above field plate 454. Wiring electrode 452 also overlaps gate electrode 38 in plan view, but is not limited thereto. A parasitic capacitance is formed by wiring electrode 452 and field plate 454.

As described in Variation 3 of Embodiment 1, the drain-source capacitance of vertical GaN transistor 2 needs to be small relative to the drain-source capacitance of lateral GaN transistor 3 in order to make the intermediate potential during OFF time small. In addition to the method of making the drain-source capacitance of vertical GaN transistor 2 small as in Variation 3, there is a method of making the drain-source capacitance of lateral GaN transistor 3 large.

An external capacitor may be separately connected in order to make the drain-source capacitance of lateral GaN transistor 3 large. However, since a parasitic inductance occurs between nitride semiconductor device 1 and the external capacitor, high-speed operation is prone to be unstable.

In view of this, in the present variation, wiring electrode 452 connected to drain electrode 46 and field plate 454 connected to source electrode 42 overlap each other via insulating film 50 as viewed from above, as illustrated in FIG. 7. Since the overlapping region serves as a capacitor, the drain-source capacitance of lateral GaN transistor 3 can be made large.

As described above, in the present variation, it is possible to use a low-breakdown-voltage lateral GaN transistor as lateral GaN transistor 3 by lowering the intermediate potential. Therefore, nitride semiconductor device 401 provides the advantageous effect of enabling higher-speed switching.

### Variation 5

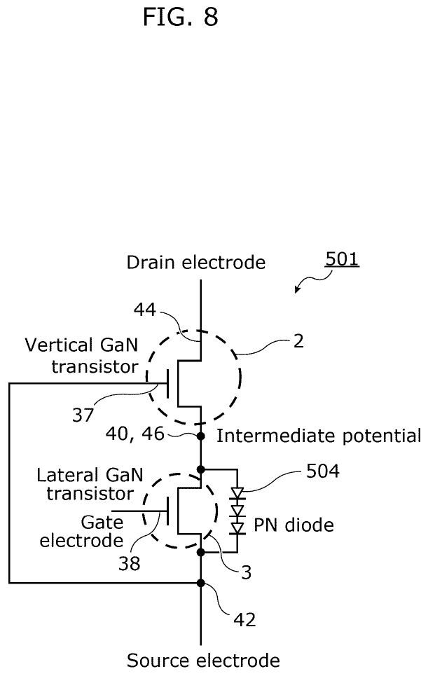

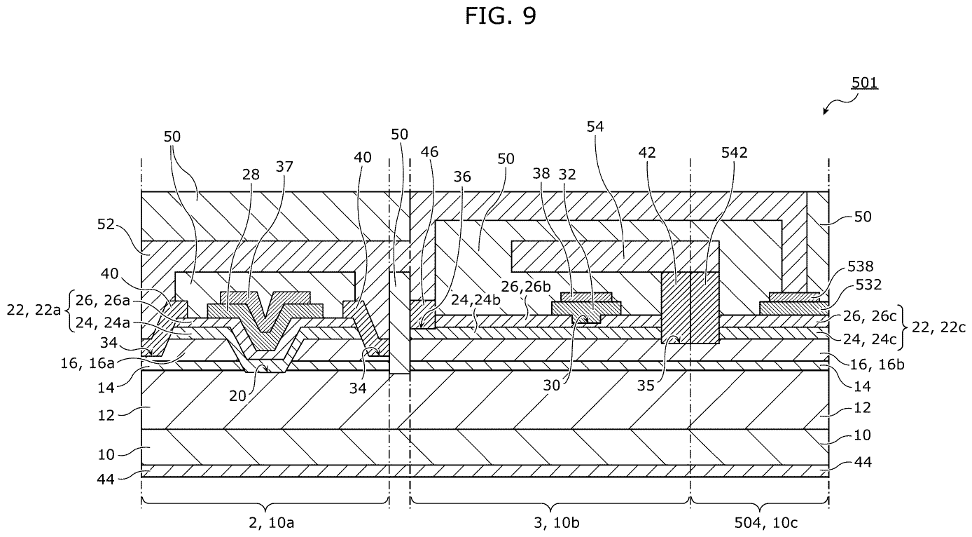

Next, a nitride semiconductor device according to Variation 5 will be described with reference to FIG. 8, FIG. 9, and FIG. 10.

FIG. 8 is a circuit diagram of nitride semiconductor device 501 according to Variation 5 of the present embodiment. As compared to nitride semiconductor device 1 illustrated in FIG. 2, nitride semiconductor device 501 illustrated in FIG. 8 is different in that a plurality of PN diodes 504 are included.

As illustrated in FIG. 8, the plurality of PN diodes 504 are connected to one another in series and are connected between drain electrode 46 and source electrode 42 of lateral GaN transistor 3. Specifically, the anode electrode of one of the plurality of PN diodes 504 is electrically connected to drain electrode 46 of lateral GaN transistor 3. The cathode electrode of another one of the plurality of PN diodes 504 is electrically connected to source electrode 42. Note that a total number of PN diodes 504 may be only one.

When the intermediate potential becomes greater than the start-up voltage of the plurality of PN diodes 504, current starts to flow through PN diodes 504. Therefore, the intermediate potential does not become greater than or equal to the start-up voltage. The intermediate potential greater than the breakdown voltage of lateral GaN transistor 3 causes a breakdown of lateral GaN transistor 3; however, by designing the start-up voltage of the plurality of PN diodes 504 to be less than or equal to the breakdown voltage of lateral GaN transistor 3, it is possible to suppress the breakdown of lateral GaN transistor 3. Note that the start-up voltage of the plurality of PN diodes 504 can be designed to a desired start-up voltage by adjusting the total number of PN diodes 504 connected in series. For example, the start-up voltage of one PN diode 504 formed using a GaN material is typically about 3 V. Therefore, the start-up voltage becomes about 9 V if, for example, three PN diodes 504 are connected in series.

PN diodes 504 may be externally connected. In the case of external PN diodes 504, however, the parasitic inductance between nitride semiconductor device 501 and PN diodes 504 becomes large, and high-speed operation is thus prone to be unstable. In view of this, in the present variation, PN diodes 504 are integrated on substrate 10 on which vertical GaN transistor 2 and lateral GaN transistor 3 are provided, as illustrated in FIG. 9. Note that FIG. 9 is a cross-sectional view of nitride semiconductor device 501 according to Variation 5 of the present embodiment.

As illustrated in FIG. 9, PN diode 504 includes third portion 22c of channel layer 22, p-type semiconductor layer 532, anode electrode 538, and cathode electrode 542. PN diode 504 is provided in third region 10c that overlaps neither first region 10a nor second region 10b in the plan view of substrate 10. Third region 10c is a region in which PN diode 504 is provided, and can be specifically regarded as the region between p-type semiconductor layer 532 and cathode electrode 542, both inclusive.

Third portion 22c of channel layer 22 is a portion of channel layer 22, and is a region overlapping third region 10c in the plan view of substrate 10. Third portion 22c of channel layer 22 includes third portion 24c of electron transport layer 24 and third portion 26c of electron supply layer 26. P-type semiconductor layer 532 and a 2DEG that is generated in third portion 24c of electron transport layer 24 form a p-n junction of the main body of PN diode 504.

P-type semiconductor layer 532 is an example of the fifth nitride semiconductor layer of the second conductivity type, and is provided between anode electrode 538 and channel layer 22. P-type semiconductor layer 532, for example, includes p-type GaN and is provided in contact with third portion 26c of electron supply layer 26.

Anode electrode 538 is an electrode connected to drain electrode 46. Anode electrode 538 is provided in contact with the upper surface of p-type semiconductor layer 532.

Cathode electrode 542 is an electrode connected to source electrode 42. Specifically, cathode electrode 542 is provided along the inner surface of source opening portion 35. Cathode electrode 542 is in contact with current block layer 16 and third portion 24c of electron transport layer 24. Although cathode electrode 542 is also in contact with third portion 26c of electron supply layer 26, it need not be in contact with third portion 26c of electron supply layer 26.

Note that cathode electrode 542 may be formed integrally with source electrode 42. That is to say, a single electrode may function as both source electrode 42 of lateral GaN transistor 3 and cathode electrode 542 of PN diode 504. In this case, the boundary between second region 10b and third region 10c may be regarded as the center of the integrated electrode, for example.

Third portion 22c of channel layer 22, p-type semiconductor layer 532, anode electrode 538, and cathode electrode 542 that are included in PN diode 504 can be formed by the same processes as those for forming second portion 22b of channel layer 22, gate layer 32, gate electrode 38, and source electrode 42, respectively, that are included in lateral GaN transistor 3. That is to say, PN diode 504 can be fabricated concurrently with vertical GaN transistor 2 and lateral GaN transistor 3. Therefore, providing PN diode 504 does not cause an increase in the processing cost.

FIG. 10 is a plan view of nitride semiconductor device 501 according to Variation 5 of the present embodiment. PN diode 504 is provided in region 11c illustrated in FIG. 10. A low-current device is sufficient as PN diode 504, so it is not necessary to secure a large area for PN diode 504. Therefore, since region 11c can be made small as compared to regions 11a and 11b, loss in the area is extremely small.

As described above, nitride semiconductor device 501 according to the present variation provides the advantageous effect of enabling high-current operation and high-speed switching with stability and also the advantageous effect of suppressing the breakdown of lateral GaN transistor 3.

### Embodiment 2

Next, Embodiment 2 will be described.

As compared to Embodiment 1, Embodiment 2 is different mainly in that a plurality of units, each including a vertical GaN transistor and a lateral GaN transistor, are provided. The following description will focus on the points different from Embodiment 1 and will omit or simplify common points.

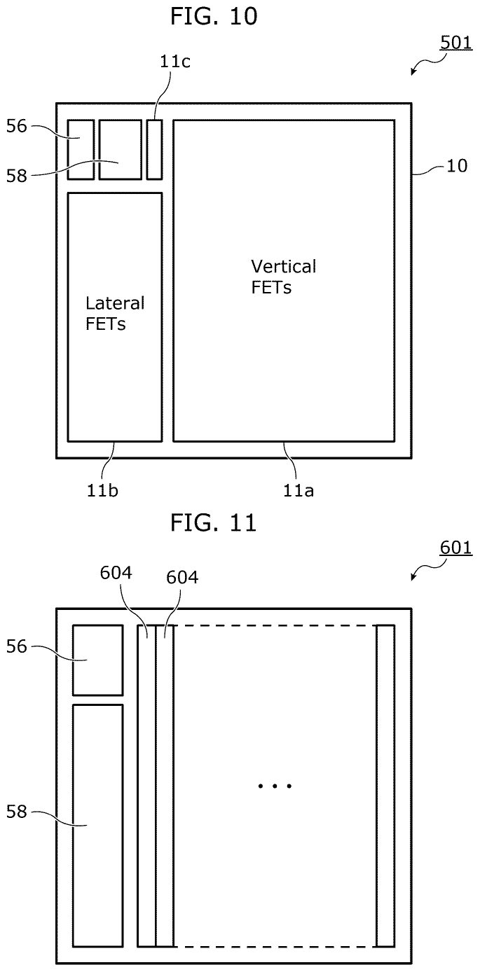

FIG. 11 is a plan view of nitride semiconductor device 601 according to the present embodiment.

In Embodiment 1, as illustrated in FIG. 3, all of the plurality of vertical GaN transistors 2 are disposed in a region separate from the region in which all of the plurality of lateral GaN transistors 3 are disposed. In contrast, in Embodiment 2, as illustrated in FIG. 11, unit 604 includes one or more of the plurality of vertical GaN transistors 2 and one or more of the plurality of lateral GaN transistors 3, and at least two units 604 are arranged side by side.

Unit 604 includes, for example, one vertical GaN transistor 2 and one lateral GaN transistor 3 illustrated in any one of FIG. 1, FIG. 4, FIG. 5, FIG. 6, and FIG. 7. By arranging units 604 side by side, it is possible to alternately arrange vertical GaN transistor 2 and lateral GaN transistor 3 one by one as illustrated in FIG. 11.

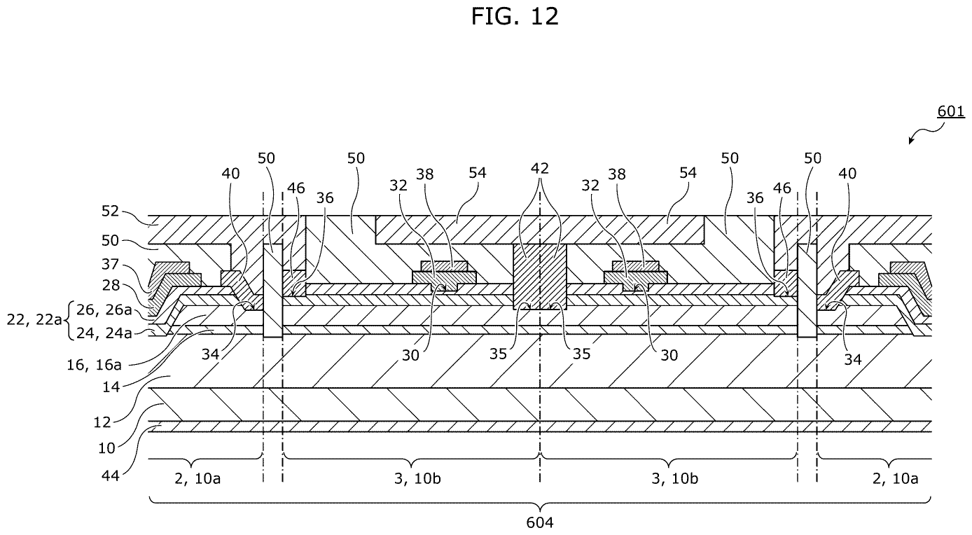

Alternatively, unit 604 may include two or more vertical GaN transistors 2 and two or more lateral GaN transistors 3. FIG. 12 is a cross-sectional view of nitride semiconductor device 601 according to the present embodiment.

Nitride semiconductor device 601 illustrated in FIG. 12 includes, as unit 604, one or two vertical GaN transistors 2 and two lateral GaN transistors 3. In unit 604, two lateral GaN transistors 3 disposed symmetrically with respect to source electrodes 42 are regarded as a unit. In the example illustrated in FIG. 12, source electrodes 42 of lateral GaN transistors 3 can be shared. This leads to a higher area efficiency, thereby providing an advantage that nitride semiconductor device 601 can be downsized.

As described above, forming vertical GaN transistor 2 and lateral GaN transistor 3 adjacent to each other within one region reduces the parasitic inductance between vertical GaN transistor 2 and lateral GaN transistor 3, thereby providing an advantageous effect of making it more suited for high-speed operation. In addition, when current flows through vertical GaN transistor 2, drift layer 12 provided in the lower portion of lateral GaN transistor 3 can also be used to conduct current, thereby providing an advantageous effect of reducing the on-resistance of vertical GaN transistor 2.

As described above, nitride semiconductor device 601 according to Embodiment 2 can more stably perform high-current operation and high-speed switching at high speed and can also reduce loss through reduction of the on-resistance.

### Variations of Embodiment 2

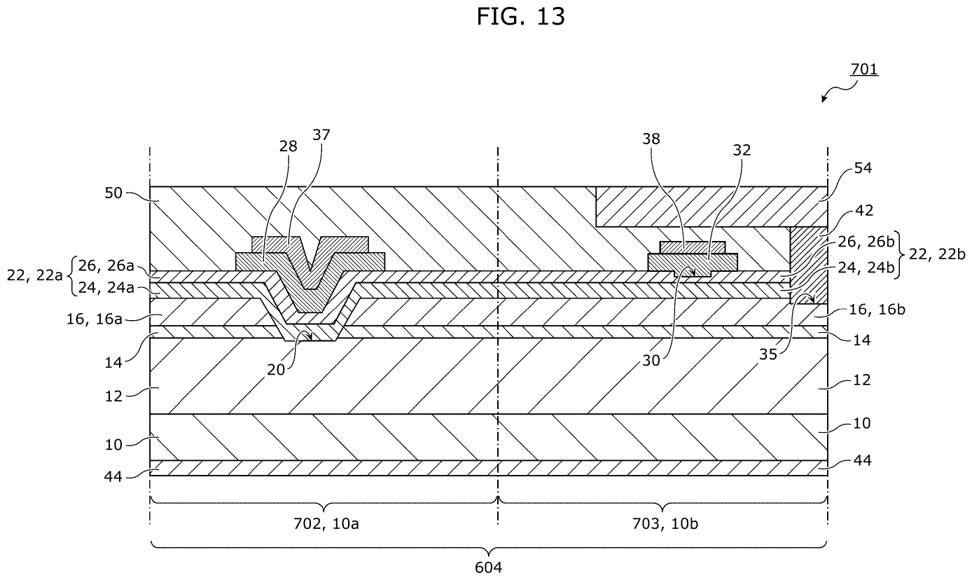

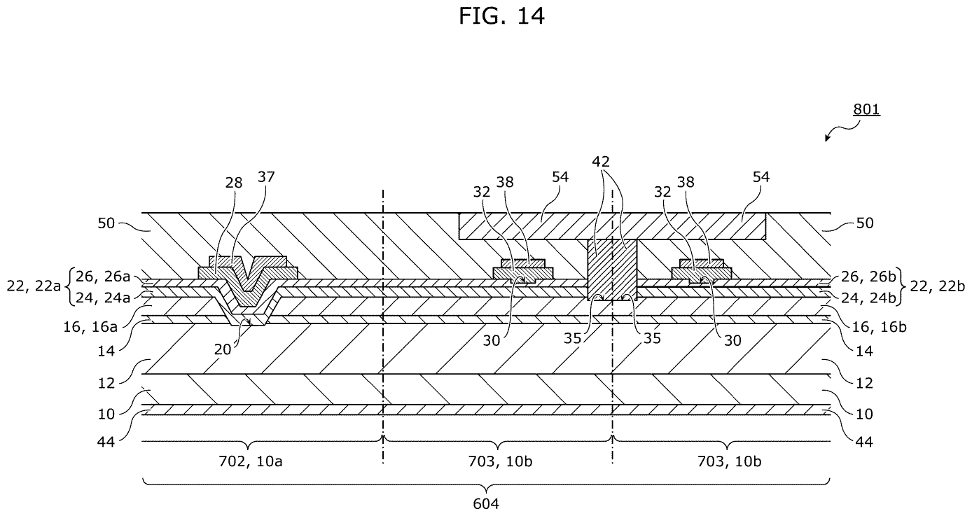

Next, variations of Embodiment 2 will be described with reference to FIG. 13 and FIG. 14. The following description will focus on the points different from Embodiment 2 and will omit or simplify common points.

FIG. 13 is a cross-sectional view of nitride semiconductor device 701 according to Variation 1 of Embodiment 2. FIG. 14 is a cross-sectional view of nitride semiconductor device 801 according to Variation 2 of Embodiment 2.

As in Embodiment 2, FIG. 13 and FIG. 14 each show a configuration corresponding to unit 604. Nitride semiconductor devices 701 and 801 each include vertical GaN transistor 702 and lateral GaN transistor 703. Vertical GaN transistor 702 is different from vertical GaN transistor 2 in that source electrode 40 is not included. Lateral GaN transistor 703 is different from lateral GaN transistor 3 in that drain electrode 46 is not included.

The current path is as follows: After flowing from drain electrode 44 of vertical GaN transistor 702 and passing through substrate 10, drift layer 12, and channel layer 22 of vertical GaN transistor 702, the current flows into channel layer 22 and source electrode 42 of lateral GaN transistor 703. Since no voltage is externally applied to the intermediate potential, which is the source potential of vertical GaN transistor 702 and the drain potential of lateral GaN transistor 703, no electrode is necessary. Note that in the present variation, current block layer 16 is electrically connected to source electrode 42 of lateral GaN transistor 703.

With such a configuration, in addition to the advantageous effects provided in Embodiment 2, it is possible to eliminate the region in which the source electrode of vertical GaN transistor 702 and the drain electrode of lateral GaN transistor 703 are formed. Therefore, the length of unit 604 can be extremely short. As a result, nitride semiconductor devices 701 and 801 can be implemented in a smaller area. In addition, the manufacturing cost of nitride semiconductor devices 701 and 801 can be reduced.

Note that in nitride semiconductor device 801 illustrated in FIG. 14, lateral GaN transistors 703 are formed symmetrically with respect to source electrodes 42 as in nitride semiconductor device 601 illustrated in FIG. 12. By sharing source electrodes 42, it is possible to further increase the area efficiency.

As described above, with nitride semiconductor devices 701 and 801 according to these variations, further downsizing can be achieved in addition to the advantageous effects provided in Embodiment 2. Nitride semiconductor devices 701 and 801 also provide the advantageous effect of reducing the manufacturing cost thereof.

### OTHER EMBODIMENTS

Nitride semiconductor devices according to one or more aspects have been described above based on exemplary embodiments, but the present disclosure is not limited to these embodiments. Various modifications of the exemplary embodiments as well as forms resulting from combinations of constituent elements from different exemplary embodiments that may be conceived by those skilled in the art are included within the scope of the present disclosure so long as such modifications and forms do not depart from the essence of the present disclosure.

For example, a layer not illustrated may be provided between the constituent elements such as the semiconductor layers, insulating films, and electrodes illustrated in the drawings, so long as such a layer does not interfere with the device operation. For example, an AlN layer having a thickness of approximately 1 nm may be provided between electron transport layer 24 and electron supply layer 26. This suppresses alloy scattering, thereby improving channel mobility and enabling reduction in the on-resistance.

Further, for example, each of the constituent elements such as the semiconductor layers, insulating films, and electrodes illustrated in the drawings may have a single-layer structure or may have a multilayer structure. For example, drift layer 12 may include a plurality of n-type nitride semiconductor layers having different impurity concentrations.

Furthermore, for example, the first conductivity type may be the p-type and the second conductivity type may be the n-type.

In addition, various changes, substitutions, additions, omissions, and so on, can be carried out in each of the above embodiments within the scope of the claims or their equivalents.

### INDUSTRIAL APPLICABILITY

The present disclosure can be used as a power device capable of high-current operation and high-speed switching, and is used for a power source circuit, an inverter circuit, or the like of in-vehicle equipment or industrial equipment, for example.

1. A nitride semiconductor device comprising:
a substrate;
a channel layer provided above the substrate and including a nitride semiconductor as a main component;
a vertical transistor provided in a first region in a plan view of the substrate, the vertical transistor being a normally-on transistor; and
a lateral transistor provided in a second region different from the first region in the plan view of the substrate, the lateral transistor being a normally-off transistor, wherein
the vertical transistor includes:
a first portion that is a portion of the channel layer and overlaps the first region in the plan view of the substrate;
a first gate electrode provided above the first portion; and
a first drain electrode provided below the substrate,
the lateral transistor includes:
a second portion that is a portion of the channel layer and overlaps the second region in the plan view of the substrate;
a second gate electrode provided above the second portion; and
a second source electrode provided above the substrate,
the first gate electrode and the second source electrode are electrically connected to each other, and
a source potential of the vertical transistor and a drain potential of the lateral transistor are equal.

2. The nitride semiconductor device according to claim 1, further comprising:
a first nitride semiconductor layer that is of a first conductivity type and is provided between the substrate and the channel layer; and
a second nitride semiconductor layer that is of a second conductivity type and is provided between the first nitride semiconductor layer and the channel layer, the second conductivity type having a polarity opposite to a polarity of the first conductivity type.

3. The nitride semiconductor device according to claim 2, wherein
the vertical transistor further includes a first source electrode set to the source potential, and
the lateral transistor further includes a second drain electrode set to the drain potential.

4. The nitride semiconductor device according to claim 3, wherein
of the second nitride semiconductor layer, a portion overlapping the first region and a portion overlapping the second region in the plan view of the substrate are electrically isolated from each other.

5. The nitride semiconductor device according to claim 4, wherein
of the second nitride semiconductor layer, the portion overlapping the second region in the plan view of the substrate is electrically connected to the second source electrode.

6. The nitride semiconductor device according to claim 4, wherein
of the second nitride semiconductor layer, the portion overlapping the first region in the plan view of the substrate is electrically connected to the first source electrode.

7. The nitride semiconductor device according to claim 4, wherein
of the second nitride semiconductor layer, the portion overlapping the first region in the plan view of the substrate is electrically connected to the first gate electrode.

8. The nitride semiconductor device according to claim 1, wherein
the channel layer includes a laminated structure of a gallium nitride (GaN) layer and an aluminum gallium nitride (AlGaN) layer.

9. The nitride semiconductor device according to claim 1, further comprising:
one of an insulating layer or a third nitride semiconductor layer of a second conductivity type, the one of the insulating layer or the third nitride semiconductor layer being provided between the first gate electrode and the first portion, the second conductivity type having a polarity opposite to a polarity of a first conductivity type.

10. The nitride semiconductor device according to claim 1, further comprising:
a fourth nitride semiconductor layer that is of a second conductivity type and is provided between the second gate electrode and the second portion, the second conductivity type having a polarity opposite to a polarity of a first conductivity type.

11. The nitride semiconductor device according to claim 1, wherein
the second portion includes an impurity region provided in a range overlapping the second gate electrode in the plan view of the substrate, and
the second gate electrode is electrically connected to the impurity region.

12. The nitride semiconductor device according to claim 3, further comprising:
source wiring electrically connected to the second source electrode; and
drain wiring electrically connected to the second drain electrode, wherein
the source wiring and the drain wiring partially overlap each other in the plan view of the substrate.

13. The nitride semiconductor device according to claim 3, further comprising:
a PN diode including (i) an electrode connected to the second drain electrode and (ii) a fifth nitride semiconductor layer that is of the second conductivity type and is provided between the electrode and the channel layer.

14. The nitride semiconductor device according to claim 13, further comprising:
a plurality of PN diodes each of which is the PN diode, wherein
the plurality of PN diodes are connected in series.

15. The nitride semiconductor device according to claim 1, further comprising:
a plurality of vertical transistors each of which is the vertical transistor; and
a plurality of lateral transistors each of which is the lateral transistor, wherein
the plurality of vertical transistors are arranged adjacent to each other in a third region in the plan view of the substrate, and
the plurality of lateral transistors are arranged adjacent to each other in a fourth region not overlapping the third region in the plan view of the substrate.

16. The nitride semiconductor device according to claim 1, further comprising:
a plurality of vertical transistors each of which is the vertical transistor; and
a plurality of lateral transistors each of which is the lateral transistor, wherein
the plurality of vertical transistors and the plurality of lateral transistors are alternately arranged in the plan view of the substrate.

17. The nitride semiconductor device according to claim 2, wherein
of the second nitride semiconductor layer, a portion overlapping the second region in the plan view of the substrate is electrically connected to the second source electrode, and
of the second nitride semiconductor layer, a portion overlapping the first region and the portion overlapping the second region in the plan view of the substrate are not electrically isolated from each other.
